(19) United States
(12) Patent Application Publication
(10) Pub. No.: US 2010/0294431 A1
(43) Pub. Date: Nov. 25, 2010

(54) EQUIPMENT FOR PRODUCING SEMICONDUCTORS, CORRESPONDING PUMPING DEVICE AND SUBSTRATE HOLDER

(76) Inventor: Philippe Maquin, Annecy (FR)

Correspondence Address: Carmen Patti Law Group, LLC, One N. LaSalle Street, 44th Floor, Chicago, IL, 60602, US

(21) Appl. No.: 12/734,598

(22) PCT Filed: Nov. 21, 2008
(86) PCT No.: PCT/FR2008/052101

§ 371 Date: Jul. 16, 2010

(30) Foreign Application Priority Data
Nov. 21, 2007 (FR) 0759189

(51) Int. Cl. C23F 1/08; F04B 49/00; B05C 11/00; C23C 16/00

(52) U.S. Cl. 156/345.26; 137/565.01; 118/692; 156/345.51; 118/728

(57) ABSTRACT

The invention relates to a piece of equipment for producing semiconductors, comprising a process chamber (2), a substrate holder (5) for holding a substrate (6) for processing within said chamber (2) and a pumping device (4), comprising a vacuum pump (7) in which a flow of gas for pumping may flow between a gas inlet (9) and a gas outlet (10) of which said inlet (9) is connected to the process chamber (2), the substrate holder (5) and the vacuum pump (7) being in the same axis (12), the substrate holder (5) being arranged upstream of said inlet (9) of said vacuum pump (7) in the flow of gas for pumping, characterised in that the pumping device (4) comprises a gas pressure regulation means (8) at the outlet (10) of the vacuum pump (7), for controlling the pressure of the gas at the inlet (9) of the vacuum pump (7) and that the substrate holder (5) comprises at least three support branches (21) connected to a support (20) on the substrate holder (5) in order to fix the support (20) to the process chamber (2) and to provides services to the support (20), at least one branch (21) comprising at least one duct (22), for the passage of said services.

The present invention pertains to a piece of equipment for the manufacture of semiconductors, and a corresponding pumping device and substrate holder.

The processes of manufacturing semiconductors and microelectronic mechanical systems (MEMS) proceed in the equipment that comprise process chambers with controlled atmospheres at subatmospheric pressures.

Vacuum pumps, in particular turbomolecular pumps, are used at the output of the chamber whenever the processes require particularly advanced levels of vacuum, especially for obtaining quality plasmas that improve the processes, such as by encouraging anisotropic etching.

As substrate wafers have continued to increase in dimensions (300 mm and 450 mm), the volume of the process chambers has also increased, and it is becoming difficult in some situations to obtain deposits or etchings that are perfectly uniform over the entire surface of the substrate.

In order to remedy this, industrial firms have developed solutions consisting, for example, of installing several small turbomolecular pumps within the process chamber.

These installations might not be sufficient to make pumping uniform on the substrate's periphery, particularly the border between two small successive pumps, and may further exhibit difficulties for controlling pressure within the process chamber.

The purpose of the present invention is therefore to propose a piece of equipment for manufacturing semiconductors, a corresponding pumping device and substrate-holder which make it possible to improve the performance of semiconductor manufacturing processes, such as improving the uniformity of etching and depositing.

To that end, the object of the invention is a device for manufacturing semiconductors comprising a process chamber, containing a substrate-holder, capable of supporting a substrate that must be treated within the chamber, and a pumping device comprising a vacuum pump in which a gas flow to be pumped may circulate between a gas intake of said pump and a gas exhaust of said pump, and whose intake is placed in contact with the process chamber, the substrate holder and vacuum pump possessing the same axis, the substrate holder being disposed ahead of the intake of the vacuum pump within the flow of the gases to be pumped. According to the invention, the pumping device comprises a gas to pressure regulation means at the exhaust of the vacuum pump, capable of controlling the pressure of the gases at the intake of the vacuum pump and the substrate holder comprise at least three support branches connected to a support of the substrate holder, both for fastening said support onto the process chamber and for carrying service lines to said support, at least one of said branches comprising at least one conduit to allow said service lines to travel.

Depending on other characteristics of the equipment,
at least one first branch is devoted to allowing through electrical cables and at least one second branch is devoted to allowing through fluids.
at least one third branch is devoted to allowing through a radio-frequency feed,
said branches exhibiting a transversal profile which is aerodynamic in shape,
said branches are disposed in a star pattern in a plane perpendicular to said axis.
the regulation means comprises a regulation valve located at the exhaust of the vacuum pump,
the regulation means comprises a neutral gas injection at the exhaust of the vacuum pump,
the axis is vertically oriented,
the equipment is suitable for implementing an etching and deposition process known as HDP CVD (High Density Plasma Chemical Vapor Deposition)

A further object of the invention is a pumping device comprising a vacuum pump within which a gas to be pumped may travel between a gas intake and a gas exhaust, and whose intake is capable of being placed in contact with a process chamber of a device for manufacturing semi conductors containing a substrate holder, capable of supporting a substrate that must be treated, the substrate holder being disposed ahead of said input of said vacuum pump within the flow of the gases to be pumped, the axis of the vacuum pump being one and the same as the axis of the substrate holder. According to the invention, the pumping device further comprises a means for regulating the pressure of the gases at the exhaust of the vacuum pump, capable of controlling the pressure of the gases at the intake of the vacuum pump, and the substrate holder comprises at least three support branches connected to a support of the substrate holder, both for fastening said support onto the process chamber and for carrying service lines to said support, at least one of said branches comprising at least one conduit to allow said service lines to travel.

According to other characteristics of the pumping device,
the regulation means comprises a regulation valve located at the exhaust of the vacuum pump and/or a neutral gas injection at the exhaust of the vacuum pump,
the regulation means is incorporated into a peripheral envelope of the vacuum pump,
the substrate holder is incorporated into a peripheral envelope of the vacuum pump.

A further object of the invention is a substrate holder comprising at least three support branches connected to a support of the substrate holder both for fastening said support onto the process chamber of a piece of equipment as described previously so that the substrate holder and the vacuum pump possess the same axis, and for carrying electrical or fluid service lines to said support, at least one of said branches comprising at least one conduit to allow said service lines to travel.

Other advantages and characteristics shall become apparent upon reading the description of the invention, as well as the attached drawings, in which:

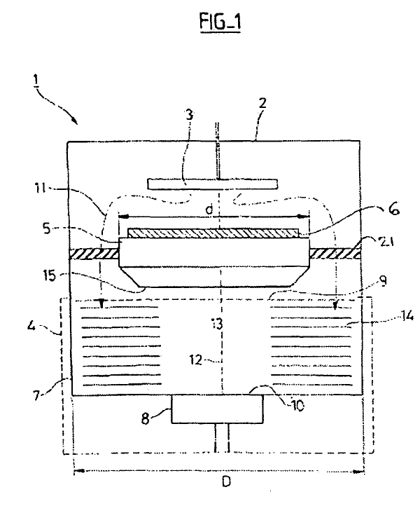

FIG. 1 is a cross-section view of the equipment for manufacturing semiconductors according to one embodiment,

FIG. 2 is a top view of the interior of the chamber of the equipment of FIG. 1, and

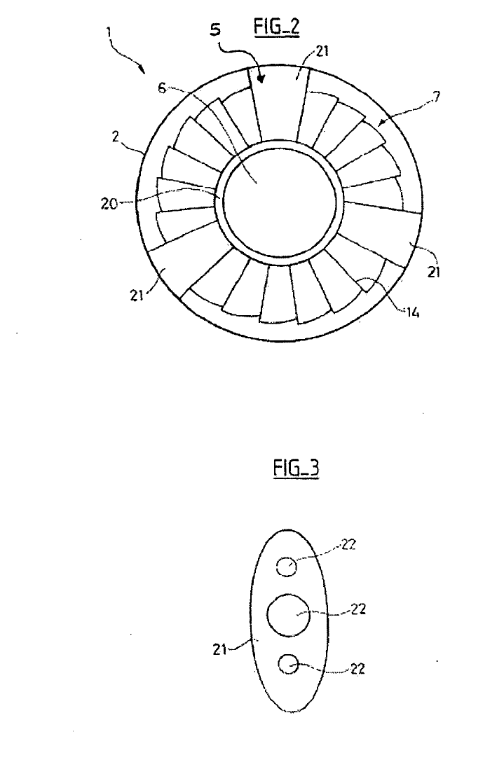

FIG. 3 is a cross-section view of a branch of a substrate holder according to one embodiment.

In these figures, identical elements are given the same reference numbers.

FIG. 1 depicts a piece of equipment 1 for manufacturing or processing semiconductors. Advantageously, the piece of equipment 1 is suitable for the implementation of an etching and deposition process known as HDP CVD (High Density Plasma Chemical Vapor Deposition).

The equipment 1 comprises a process chamber 2 connected to a process gas inlet 3, and a pumping device 4 as well. The process chamber 2 contains a substrate holder 5 capable of supporting a substrate 6 which must be treated in the chamber 2. The substrate 6 is, for example, a semiconductor wafer, preferentially 300 mm in diameter.

The pumping device 4 comprises a vacuum pump 7 and a means 8 for regulating the pressure of the pump 7 exhaust. The vacuum pump 7 may for example be turbomolecular, in which a gas flow to be pumped may circulate between a gas intake 9 of the pump 7 and a gas exhaust 10 of the pump 7. The intake 9 is placed in contact with the chamber 2 in such a way as to be able to create and maintain a vacuum within the process chamber 2 this means a subatmospheric pressure between 10⁻³ mbar and 1 mbar depending on the gas flows injected into the process chamber 2. The control of the pressure at the intake 9 of the vacuum pump 7 is done solely by the means 8 for regulating the exhaust pressure, which is placed at the outlet 10 of the vacuum pump 7. Thus, no component obstructs the pumping flow of the gases. There is no valve disrupting the stream of the gas flows 11 within the process chamber 2, which enables uniform laminar stream.

According to the embodiment of the invention depicted in FIG. 1, the substrate holder 5 and the vacuum pump 7 are coaxial along the axis 12, the substrate holder 5 being disposed ahead of the intake 9 of the vacuum pump 7, in the flow of the gases to be pumped. Very advantageously, the axis 12 is a vertically-oriented axis.

Additionally, as the equipment 1 does not require any valves ahead of the vacuum pump 7, the conductance ahead of the pumped 7 is increased, such that it is possible to choose models of turbomolecular vacuum pumps that have pumping capacities less than those which are normally used, in order to obtain the same levels of flow and pressure performance within the chamber.

Advantageously, the substrate holder 5 is positioned as close as possible to the intake 9 of the turbomolecular vacuum pump 7, facing the intake 9. One area 13 of the vacuum pump 7 is located at the intake 9 of the vacuum pump 7 at the peak of the turbomolecular pump's 7 rotor, which comprises no pumping blades 14. The rear surface 15 of the substrate holder 6 is aligned with the area 13, the substrate holder 5 being fastened to the chamber 2, in such a way that the stream of the gases 11 in the direction of the pump 7 is further optimized because the maximum pumping capacity is located at the radial ends of the pumping blades 14.

Consequently, the form factor of the equipment 1 is considerably reduced, because lower-volume process chambers may be included 2, which causes a reduction in the cost of installation and in the maintenance of the equipment 1. Furthermore, this embodiment makes it possible to reduce the response time for controlling pressure within the chamber 2 during the transitional process steps, in which the nature of the gases' flows and/or their pressure are modified.

According to another embodiment of the invention, the regulation means 8 comprises a regulation valve located at the exhaust 10 of the vacuum pump 7 and ahead of a primary vacuum pump (not depicted).

The pumping device 4 connected by fluids to the process chamber 2 may receive information on the processes implemented within the process chamber 2, such as the pressure set point and the pressure at the intake 9 of the vacuum pump 7 by means of a pressure sensor placed within the chamber 2. The regulation valve is then opened and closed through being subject to a set point.

Furthermore, it may be provided that the regulation means 8 comprises a means of injecting a neutral gas, such as nitrogen, at the exhaust 10 of the vacuum pump 7. The injection means then preferentially comprises a flow controller used to control the gas flow injected at the exhaust 10 of the pump 7.

In the same way, the regulation means 8 may control the gas injection flow rate based on the set points of the pressure within the process chamber 2 and of the pressure actually measured within the chamber 2.

It may also be provided that the regulation means 8 of the gas pressure at the exhaust 10 of the pump 7 comprise a neutral gas injection means disposed, for example, between the turbo and molecular stages of the pump 7, in order to control the pressure of the gases at the intake 9. Preferentially, injection is carried out within a purge circuit of the vacuum pump 7. However, a minimum purge flow is kept for protecting the roller bearings of the vacuum pump 7.

Furthermore, it is also possible that the regulation means 8 comprises both a regulation valve and a neutral gas injection. In this situation, the injection is located ahead of the regulation valve. The injection or the regulation valve, or both of them at the same time, are regulated in order to obtain the pressure set point demanded within the process chamber 2.

Regulation means 8 thereby disposed at the exhaust 10 of the pump 7 make it possible to reduce the response time of the regulation and the residence time of the gas species within the process chamber 2.

According to one advantageous embodiment (not depicted), the regulation means 8 is incorporated into the peripheral envelope of the turbomolecular pump 7.

It may also be provided that the substrate holder 5 is incorporated into a peripheral envelope of the vacuum pump 7.

According to one embodiment depicted in FIG. 2, the substrate holder 5 is formed of a support 20 here having the shape of a disk, for example one made of aluminum, in order to support a substrate of the same shape. The substrate holder 5 further comprises at least three support branches 21 connected to the support 20 and disposed at the periphery of the support 20 use both to fasten the support 20 onto an internal wall of the process chamber 2, and also to carry the electrical or fluid service lines to the support 20 of the substrate holder 5. The branches 21 of the support thereby make it possible to fasten the support 20 onto the chamber 2 while being located as close as possible to the intake 9 of the pump 7 without preventing the rotation of the pump 7's rotor.

The support branches 21 are advantageously disposed in a star pattern within a plane perpendicular to the axis 12.

The support disk 20 possesses a diameter d slightly greater than the diameter of a substrate 6 to be treated. The outer diameter D of the vacuum pump 7 is of a diameter greater than the diameter d of the support disk 20. The outer diameter D of the pump 7 is chosen to be as low as possible, given the pumping capacity restrictions imposed on the pump 7.

As shown in FIG. 3, each branch 21 may comprise at least one conduit 22, used for example to allow through electrical cables or to allow gases or liquids to reach the substrate holder 5. The conduit 22 used to allow electrical cable through may, for example, make it possible to set up the substrate holder 5's control means, and if necessary to supply the substrate holder 5 with direct current and radio frequencies. Furthermore, the conduit 22 used to allow through gases and/or liquids may, for example, make it possible for pressurized helium to circulate in order to thermalize the substrate holder 5 and therefore the substrate 6 itself whenever it is fastened to the substrate holder 5.

Preferentially, at least one branch 21 comprising one or more conduits 22 is devoted to supplying fluids to the support 20, at least one other branch 21 comprising one or more conduits 22 for allowing through electrical cables for controlling the temperature and voltage of the support 20, and at least one more branch 21 comprising a conduit 22 for supplying a radio frequency feed to the support 20. The radio frequency feed is advantageously separate from the other electrical cables in order to avoid the formation of electrical arcs.

The branches 21 may advantageously be given a transverse profile which is aerodynamic in shape so as not to disrupt the flow of the gases to be pumped.

Such an arrangement of the substrate 5 makes it possible to carry the service lines to the support 20 and therefore to the substrate 6 undergoing the process without disrupting the uniform laminar stream of the pumping flow of the gases 11. Furthermore, this arrangement makes it possible to carry the service lines to the substrate 6 without altering the existing vacuum pumps.

Thus, during the process of manufacturing semiconductors, the process gases injected into the chamber 2 at the inlet 3 evenly flow into the process chamber 2 around the substrate 6, then pass between the branches 21 of the substrate holder 5 and are then pumped by the vacuum pump 7 from the input 9 to the output 10.

A piece of equipment 1 whose substrate holder 5 is disposed above the intake 9 of the vacuum pump 7, and whose pumping device 4 comprises a means 8 for regulating the exhaust pressure of the vacuum pump 7 capable of controlling the pressure at the intake 9 of the vacuum pump 7, makes it possible to enjoy optimized conditions for manufacturing semiconductors.

1. A piece of equipment for manufacturing semiconductors comprising a process chamber (2), containing a substrate-holder (5) capable of supporting a substrate (6) that must be treated within said chamber (2), and a pumping device (4) comprising a vacuum pump (7) in which a gas flow to be pumped may circulate between a gas intake (9) of said pump (7), in contact with the process chamber (2), and a gas exhaust (10) of said pump (7), the substrate holder (5) and the vacuum pump (7) possessing the same axis (12), the substrate holder (5) being disposed ahead of said intake (9) of the vacuum pump (7) within the flow of the gases to be pumped, wherein the pumping device (4) comprises a means (8) for regulating the pressure of the gases at the exhaust (10) of said vacuum pump (7), capable of controlling the pressure of the gases at the intake (9) of said vacuum pump (7) and in that the substrate holder (5) comprises at least three support branches (21) connected to a support (20) of the substrate holder (5), both for fastening said support (20) onto the process chamber (2) and for carrying service lines to said support (20), at least one of said branches (21) comprising at least one conduit (22) to allow said service lines to travel.

2. A piece of equipment for manufacturing semiconductors according to claim 1, wherein at least one first branch is devoted to allowing through electrical cables and at least one second branch is devoted to allowing through fluids.

3. A piece of equipment for manufacturing semiconductors according to claim 2, wherein at least one third branch is devoted to allowing through a radio frequency feed.

4. A piece of equipment for manufacturing semiconductors according to claim 1, wherein said branches (21) exhibit a transversal profile which is aerodynamic in shape.

5. A piece of equipment for manufacturing semiconductors according to claim 1, wherein said branches (21) are disposed in a star pattern in a plane perpendicular to said axis (12).

6. A piece of equipment for manufacturing semiconductors according to claim 1, wherein the regulation means (8) comprises a regulation valve located at the exhaust of the vacuum pump (7) and/or a neutral gas injection at the exhaust of the vacuum pump (7).

7. A piece of equipment for manufacturing semiconductors according to claim 1, wherein the axis (12) is vertically oriented.

8. A piece of equipment for manufacturing semiconductors according to claim 1, adapted to implement an HDPCVD etching and deposition process (“High Density Plasma Chemical Vapor Deposition”).

9. A pumping device comprising a vacuum pump (7) in which a gas flow to be pumped may circulate between a gas intake (9) and a gas exhaust (10) and whose intake (9) is placed in contact with the process chamber (2) of a piece of equipment (1) for manufacturing semiconductors containing a substrate holder (5) disposed ahead of said intake (9) of said vacuum pump (7), the axis (12) of the vacuum pump (7) being one and the same as the axis (12) of the substrate holder (5), wherein it comprises a means (8) for regulating the pressure of the gases at the exhaust (10) of said vacuum pump (7), capable of controlling the pressure of the gases at the intake (9) of said vacuum pump (7) and in that the substrate holder (5) comprises at least three support branches (21) connected to a support (20) of the substrate holder (5), both for fastening said support (20) onto the process chamber (2) and for carrying service lines to said support (20), at least one of said branches (21) comprising at least one conduit (22) to allow said service lines to travel.

10. A pumping device according to claim 9, wherein said regulation means (8) comprises a regulation valve located at the exhaust (10) of said vacuum pump (7) and/or an injection of neutral gas at the exhaust (10) of said vacuum pump (7).

11. A pumping device according to claim 9, wherein said regulation means (8) is incorporated into a peripheral envelope of said vacuum pump (7).

12. A pumping device according to claim 9, wherein the substrate holder (5) is incorporated into a peripheral envelope of said vacuum pump (7).

13. A substrate holder comprising at least three support branches (21) connected to a support (20) of the substrate holder (5), both for fastening said support (20) onto a process chamber (2) of a piece of equipment (1) according to claim 1, such that the substrate holder (5) and the vacuum pump (7) possess the same axis (12), and also for carrying electrical or fluid service lines to said support (20), at least one of said branches (21) comprising at least one conduit (22) to allow said service lines to travel.
